(19) United States
(12) Patent Application Publication
(10) Pub. No.: US 2017/0334730 A1
(43) Pub. Date: Nov. 23, 2017

(54) METHOD FOR PRODUCING CHLORINATED OLIGOSILANES

(71) Applicant: NAGARJUNA FERTILIZERS AND CHEMICALS LIMITED, HYDERABAD (IN)

(72) Inventors: Christian BAUCH, Muldenstein (DE); Sven HOLL, Gueckingen (DE); Norbert AUNER, Glashuetten (DE); Javad MOHSSEN, Leipzig (DE)

(21) Appl. No.: 15/535,960

(22) PCT Filed: Dec. 15, 2014
(86) PCT No.: PCT/EP2014/077814

§ 371 Date: Jun. 14, 2017

(51) Int. Cl. C01B 33/107; B01D 3/00; C09D 1/00; H01L 21/02

(52) U.S. Cl. CPC C01B 33/107; C09D 1/00; B01D 3/009; C01B 33/10778; H01L 21/02123

(57) ABSTRACT

The present invention relates to a process for preparing chlorinated oligosilanes, wherein chlorinated polysilane having an empirical formula of SiCl_{1.0-2.8} and/or a mixture comprising the chlorinated polysilane is reacted with elemental chlorine or a chlorine-containing mixture. Additionally claimed are chlorinated oligosilanes prepared by the process and the use thereof for production of semiconductors and/or hard coatings.

The present invention relates to a process for preparing chlorinated oligosilanes and to the use of the chlorinated oligosilanes prepared by the process for production of semiconductors and/or hard coatings.

M. Schmeisser, P. Voss, Zeitschrift für anorganische and allgemeine Chemie, 1964, 334, 50-56 describe the reaction of solid chlorinated polysilanes (SiCl₂)ₓ with chlorine gas. A 1:1 mixture of chlorine gas and nitrogen is passed at 60° C. through a vessel containing the solid material. A clear layer of low-viscosity liquid forms gradually on the solid material. After three days, the solid material has disappeared completely and the remaining liquid mixture is fractionated. Isolated components are Si₂Cl₆, Si₃Cl₈, Si₄Cl₁₀ and Si₅Cl₁₂. SiCl₄ is not formed during this reaction, nor in a second reaction with a solution of (SiCl₂)ₓ in CCl₄.

The process according to Schmeisser and Voss does not lead to complete conversion of the chloropolysilane and is unsuitable especially for greater batch volumes if there is only poor contact between the gas phase and chloropolysilane.

E. Bonitz, Angewandte Chemie, 1966, 78, 475-482 and DE 1132901 B describe the reaction of chlorine gas with CaSi₂ which has been activated by grinding in the presence of chlorine-containing diluents. The silicide reacts with chlorine gas at 20-40° C. at first to give elemental silicon and CaCl₂ and then to give silicon monochloride SiCl. Further addition of chlorine gas leads to scission of Si—Si bonds and, depending on the ratio of chlorine gas added to starting material, various Si—Cl compounds are obtained. Continued chlorination leads ultimately to catenated compounds SiₙCl₂ₙ₊₂ with molecular masses M=170-700. DE 1132901 B additionally discloses that silicon or silicon alloys also react in the same way in the presence of catalytically active metals such as Cu or Fe. Reaction temperatures between 0° C. and 250° C. are stated, preferably 20° C. to 150° C. Diluents mentioned are CCl₄, SiCl₄, tetrachloroethane and liquid chlorinated polysilanes. The reaction rate can be accelerated by means of elevated pressure during the introduction of chlorine. SiCl₄ is not formed during the reaction.

The process according to Bonitz entails the activation of solid silicon-containing materials by grinding in the presence of chlorine-containing diluents before the reaction with chlorine gas can be conducted. This corresponds to an additional processing step in addition to the chlorination, which requires either a specific, mechanically very robust reactor construction or an additional piece of equipment with subsequent transfer of the activated reactive material in the chlorination reactor. In addition, CaCl₂ and/or the catalyst metals remain in the reaction mixture after the reaction, and these, being metal impurities, cause problems for the isolation of very pure end products.

It is an object of the present invention to provide an improved process for preparing chlorinated oligosilanes, chlorinated oligosilanes prepared by the process, and a use for the chlorinated oligosilanes prepared.

This object is achieved by the process as claimed in claim 1, the product as claimed in claim 14 and the use as claimed in claim 15. Preferred embodiments are detailed in the dependent claims.

In processes of the invention for preparation of chlorinated oligosilanes, chlorinated polysilane having an empirical formula of SiCl_{1.0-2.8} and/or a mixture comprising the chlorinated polysilane is reacted with elemental chlorine or a chlorine-containing mixture.

Preference is given to using chlorinated polysilane having an empirical formula of SiCl_{1.6-2.2}. This process enables the preparation of chlorinated oligosilanes with good yield and with high purity, the process being easily performable.

Chlorinated polysilanes in the context of the process of the invention are compounds that consist of silicon and chlorine and have at least one direct Si—Si bond. For performance of the process, the chlorinated polysilanes may either be in the form of the pure substance or in the form of an isomer mixture or of a mixture of compounds having different molecular weight. Oligosilanes in the context of the process of the invention refer to a subgroup of the polysilanes where the molecules have not more than six silicon atoms.

Preferably, the chlorinated polysilane has a mean chain length of n=4 to n=50, preferably n=6 to n=30, further preferably n=10 to n=25 and/or n=3.

The chain length n in the context of the process of the invention refers to the number of silicon atoms in a polysilane that are bonded either directly or indirectly to one another, without involvement of a further chemical element.

In the process of the invention, chlorinated polysilanes are reacted with chlorine gas or chlorine-containing mixtures. The chlorine-containing mixtures include gaseous mixtures with inert gases and liquid mixtures in which chlorine has been dissolved in suitable solvents. Examples of inert gases are helium, nitrogen or argon. Examples of suitable solvents are chlorinated silanes (e.g. SiCl₄) or polysilanes, preferably oligosilanes, especially preferably Si₂Cl₆, Si₃Cl₈, Si₄Cl₁₀ and/or polychlorosilane. The solvent can either be reacted with the chlorine to give the desired product and/or can be removed, preferably by distillation. If the solvent is removed, it is preferably recycled, i.e. fed back to the process.

The process of the invention can be conducted with a polysilane or a mixture of polysilanes of the said mean chain lengths without addition of diluents. The polysilane or the mixture of polysilanes can also be used in a mixture with at least one diluent. Preference is given to those diluents that do not react with chlorine under the reaction conditions. Particularly suitable diluents for performance of the process are chlorinated polysilanes SiₙCl₂ₙ₊₂ (n=2, 3, 4) or mixtures thereof, especially Si₂Cl₆ and/or Si₃Cl₈. In respect of chlorinated polysilanes as diluent, the prerequisite of stability to chlorine under the reaction conditions is not applicable.

The product mixture formed during the performance of the process of the invention contains SiCl₄ and Si₂Cl₆. SiCl₄ is formed here in a stoichiometric ratio compared to Si₂Cl₆. The molar ratio of SiCl₄ to Si₂Cl₆ in the product formed is 0.1 to 1.5, preferably 0.2 to 1.2, more preferably 0.25 to 1.

The process of the invention can be conducted under reaction conditions under which SiCl₄ at least partly distills out of the reaction mixture within the reaction period. The reaction conditions can also be chosen such that, aside from SiCl₄, at least one chlorinated oligosilane is also present in distillate obtained during the reaction period. This applies especially to Si₂Cl₆ and/or Si₃Cl₈. Compounds present in the distillate obtained during the reaction period can be admixed with chlorine gas outside the reaction vessel, and the chlorine solution thus obtained can be recycled into the reactor.

Preferably, the chlorination reaction is conducted in at least two steps in at least two different temperature ranges. In this way, higher yields and a higher purity of the products are obtained. Further preferably, the first temperature range is 100° C. to 140° C. and the second temperature range is 145° C. to 175° C., preferably 155° C. to 170° C. The first temperature range can be attained exclusively or predominantly via the enthalpy of reaction released. In the case of performance of such a two-stage process, it is possible to avoid spontaneous ignition of the reaction mixture that can occur in the case of immediate heating to the higher temperature range.

The chlorination reaction is preferably conducted within a pressure range from 100 hPa to 2000 hPa, preferably 800 hPa to 1500 hPa, further preferably 100 hPa to 1400 hPa, especially preferably 1100 hPa to 1300 hPa.

In the process of the invention, in order to obtain chlorinated oligosilanes, the reaction with chlorine may be followed by a further process step, especially a distillation.

The process of the invention is suitable for producing products that are suitable for production of semiconductors or hard material layers, especially the compounds Si₂Cl₆, Si₃Cl₈, Si₄Cl₁₀, Si₅Cl₁₂ or mixtures thereof.

In a first embodiment, the process of the invention is conducted as a batchwise process (also called charge process or badge process). Intensive mixing of the reaction mixture is advantageous here, for example by vigorous stirring.

When the process of the invention is conducted as a batchwise process and the liquid mixture is contacted with chlorine gas, the absorption of gas can be accomplished via the liquid surface alone, especially when the liquid is being stirred vigorously. It is preferable to allow the chlorine gas to flow through the liquid in the form of bubbles. A large bubble surface area and hence fine bubbles improve the contact between gas and liquid and hence the absorption of chlorine gas by the reaction solution.

When the process of the invention is conducted as a batchwise process, it is additionally possible to mix in solid chlorinated polysilanes of the empirical formula SiClₓ with x=0.05 to x=1, preferably with x=0.2 to 0.8. These are likewise reacted with chlorine gas during the process to give compounds having a higher chlorine content.

In a second embodiment of the process of the invention, it is conducted as a continuous process. For this purpose, the chlorinated polysilane or the mixture of chlorinated polysilane or the mixture with at least one diluent can be metered into a tubular reactor and contacted with chlorine gas in its interior. If an immobile reactor is used, it is advantageous to increase the contact area between gas phase and liquid by designing this reactor in the form of an upright column having random packing and to meter the liquid into the reactor from above.

When the process of the invention is conducted as a continuous process, the liquid phase and gas phase can be conducted through the tubular reactor in countercurrent.

When the process of the invention is conducted as a continuous process, the liquid phase and gas phase can be conducted through the tubular reactor in countercurrent.

In the second embodiment of the process of the invention too, the reaction conditions can be chosen such that SiCl₄ leaves the reactor at least partly in gaseous form. The reaction conditions can also be chosen such that, aside from SiCl₄, at least one chlorinated oligosilane is also present in the mixture that exits in gaseous form. This applies especially to Si₂Cl₆ and/or Si₃Cl₈.

In the second, continuous embodiment, the liquid reaction mixture can successively flow through zones at different temperature within the tubular reactor. It is advantageous here when the reaction mixture first passes through a zone with lower temperature and then a zone at higher temperature.

### WORKING EXAMPLES

### Example 1

3052.7 g of chlorinated polysilane produced by plasma chemistry are diluted with 1388.7 g of Si₂Cl₆ and introduced into an apparatus equipped with stirrer, reflux condenser and gas inlet tube. The reflux condenser is kept at 60° C. Chlorosilanes that exit from the reaction vessel are condensed in a cold trap at 0° C. The temperature of the reaction mixture is kept between 110° C. and 120° C., and 950 g of chlorine gas are introduced into the reaction mixture with vigorous stirring within 25.5 h. The pressure in the apparatus is kept within the range between 1013 hPa and 1213 hPa. Fractionation of the reaction product gives 760.1 g of SiCl₄, 3354.9 g of Si₂Cl₆ and 861.8 g of Si₃Cl₈. According to ²⁹Si NMR spectroscopy, the 401.7 g of fractionation residue contain, as well as residues of Si₃Cl₈, the compounds i-tetrasilane, neopentasilane and neohexasilane in their perchlorinated form.

### Example 2

To 505.7 g of Si₃Cl₈ are added 100.1 g of a solid having the empirical composition SiCl_{0.7} in an apparatus equipped with stirrer and gas inlet tube. The mixture is contacted with about 200 g of chlorine gas while stirring within 30 h. During the addition of chlorine, the temperature of the liquid rises as a result of the exothermic reaction from initially 23° C. to a maximum of 125° C. This maximum temperature is maintained by monitoring the rate of chlorine addition. As soon as the reaction rate decreases, as indicated by reduced chlorine absorption and decreasing temperature, the reaction is continued with external heating to 120° C. Fractionation of the reaction mixture gives 202.4 g of SiCl₄, 362.5 g of Si₂Cl₆ and 181.7 g of Si₃Cl₈. The distillation residue weighs 42.6 g.

### Example 3

5.710 kg of chlorinated polysilane produced by plasma chemistry and 5.327 kg of fractionation residue from prior chlorination batches, diluted with 19.215 kg of Si₃Cl₈, are introduced into an apparatus equipped with reflux condenser, stirrer and gas inlet tube. The reflux condenser is kept at 150° C. The reaction mixture is heated to 165° C. and, within 36 h, 6.7 kg of chlorine gas are introduced into the liquid with vigorous stirring. The pressure in the apparatus is kept between 1013 hPa and 1113 hPa. During the reaction period, 17.82 kg of a chlorosilane mixture containing mainly SiCl₄ and Si₂Cl₆ and also a small amount of Si₃Cl₈ leave the apparatus via the reflux condenser and are condensed in a second condenser at 12° C. The oligosilanes are concentrated by distilling of the majority of SiCl₄, and the distillation residue is combined with the contents of the chlorination reactor. After fractionation of this liquid, 12.660 kg of Si₂Cl₆ and 3.370 kg of Si₃Cl₈ are isolated, as well as 1.629 kg of mixed fractions. The 5.745 kg of fractionation residue contain, by ²⁹Si NMR spectroscopy, as well as residues of Si₃Cl₈, the compounds i-tetrasilane, neopentasilane and neohexasilane in their perchlorinated form.

### Example 4

26.27 kg of chlorinated polysilanes produced by plasma chemistry, diluted with 18.20 kg of fractionation residues from prior chlorination batches and 2.50 kg of Si₂Cl₆, are introduced into an apparatus equipped with stirrer, reflux condenser and gas inlet tube. The reflux condenser is kept at 60° C. The temperature of the reaction mixture is at first kept at 120° C., and it is later heated with declining chlorine absorption to 140° and finally to 155° C. 9.5 kg of chlorine gas are introduced with vigorous stirring within 50 h. The pressure within the apparatus is kept between 1013 hPa and 1250 hPa. Within the reaction period, 14.3 kg of chlorinated SiCl₄ are distilled off about every 2 h by pressure reduction and condensed in a second condenser at 12° C. Fractionation of the reactor contents gives 1.12 kg of SiCl₄/Si₂Cl₆ mixture, 20.39 kg of pure Si₂Cl₆ and 0.30 kg of Si₂Cl₆/Si₃Cl₈ mixture. 20.20 kg of fractionation residue remain, containing a mixture of Si₃Cl₈ and the perchlorinated i-tetrasilane, neopentasilane and neohexasilane.

### Example 5

63.88 g of chlorinated polysilanes produced by plasma chemistry are dissolved in 52.65 g of Si₂Cl₆. The solution is transferred into a dropping funnel at the upper end of a vertical column having random packing (diameter 2.4 cm, length 25 cm), filled with 3 mm Raschig rings. The column is heated to a constant temperature of 90° C. The reaction products are collected in a Schlenk flask at the lower end of the column which is cooled to 0° C. A gentle stream of chlorine gas through the column and the collecting flask is maintained during the reaction time. The solution is introduced dropwise into the column within h and the chlorine gas stream is maintained for a further 30 min until the majority of the liquid has passed through the column. A small amount of product remains in the column. Volatile components of the product mixture are drawn off under reduced pressure at 200° C. (63.37 g) and subsequently subjected to a fractional vacuum distillation (distillation temperatures and yields: 50° C.: 46.28 g; 100° C.: 6.45 g; 130° C.: 1.35 g).

### Example 6

### Comparative Example

223.4 g of PCS produced by plasma chemistry are mixed with 65.4 g of Si₃Cl₈. The solution is transferred into the dropping funnel of the apparatus described in example 5. The column is heated to 155° C. Once a gentle chlorine gas stream through the apparatus has been established, the tap of the dropping funnel is opened slightly. When the chlorosilane mixture meets the column packing, the mixture ignites immediately and burns with local glowing and an orange-red flame which penetrates into the column packing. The experiment is stopped.

### Example 7

The apparatus described in example 5 is supplemented with a further unheated and uninsulated column having random packing (diameter 3 cm, length 25 cm, 3 mm Raschig rings) which is inserted between the dropping funnel and heated column.

524.9 g of PCS produced by plasma chemistry are mixed with 153.7 g of Si₃Cl₈ and transferred into the dropping funnel of the apparatus. A gentle chlorine gas stream through both columns having random packing and the collecting flask is established and adjusted in accordance with the gas consumption during the reaction. The chlorosilane mixture is introduced into the upper column having random packing within 13.5 h. The upper half of this column heats up gradually to less than 50° C. The viscosity of the mixture is distinctly reduced as it passes through the upper column and the color of the orange/yellow mixture likewise becomes less intense. Material exiting from the upper column does not ignite on contact with the column packing heated to 155° C. On completion of the addition of liquid, a gentle chlorine gas stream is maintained for a further 30 min. Fractional distillation of the 892.3 g of product mixture under reduced pressure gives 185.2 g of a fraction consisting mainly of SiCl₄ and a little Si₂Cl₆, 354.7 g of a fraction consisting mainly of Si₂Cl₆ and a little Si₃Cl₈, and 223.9 g of a fraction consisting mainly of Si₃Cl₈ and a little Si₂Cl₆. This leaves a residue of 118.5 g.

1. A process for preparing chlorinated oligosilanes comprising reacting chlorinated polysilane having an empirical formula of SiCl_{1.0-2.8} and/or a mixture comprising the chlorinated polysilane with elemental chlorine or a chlorine-containing mixture.

2. The process as claimed in claim 1, wherein the chlorinated polysilane having an empirical formula of SiCl_{1.0-2.8} is chlorinated polysilane having an empirical formula of SiCl_{1.6-2.2}.

3. The process of claim 1, wherein the chlorinated polysilane has a mean chain length of n=4 to n=50.

4. The process of claim 1, wherein the reacting is conducted at a temperature of 20° C. to 300° C.

5. The process of claim 4, wherein the reacting is conducted in at least two steps in at least two different temperature ranges.

6. The process of claim 5, wherein the first temperature range is 100° C. to 140° C. and the second temperature range is 145° C. to 175° C.

7. The process as of claim 1, wherein the reacting is conducted within a pressure range from 100 hPa to 2000 hPa.

8. The process of claim 1, wherein the reacting takes place in solution with a diluent which is selected from the group consisting of Si₂Cl₆, Si₃Cl₈, Si₄Cl₁₀, Si₅Cl₁₂, and mixtures thereof.

9. The process of claim 1, wherein SiCl₄ is distilled off during the chlorination reaction.

10. The process of claim 9, wherein at least one additional chlorinated oligosilane is distilled off.

11. The process of claim 1, wherein the reacting is effected with full or partial reflux of SiCl₄ or a mixture of SiCl₄ and at least one additional chlorinated oligosilane.

12. The process of claim 1, wherein the reacting is conducted continuously in a column.

13. The process of claim 1, being conducted batchwise.

14. Chlorinated oligosilanes obtainable by the process of claim 1.

15. A process for production of semiconductors and/or hard coatings comprising incorporating chlorinated oligosilanes of claim 1.
